(19) United States
(12) Patent Application Publication
(10) Pub. No.: US 2006/0181912 A1
(43) Pub. Date: Aug. 17, 2006

(54) Low-power solid state storage controller for cell phones and other portable appliances

(76) Inventors: Sree M. Iyer, San Jose, CA (US); Larry Lawson Jones, Palo Alto, CA (US); Nicholas Antonopoulos, San Jose, CA (US); Santosh Kumar, Santa Clara, CA (US); Dan Kikinis, Saratoga, CA (US); Arockiyaswamy Venkidu, Menlo Park, CA (US)

Correspondence Address: GREENBERG TRAURIG, LLP, 1900 UNIVERSITY AVENUE, FIFTH FLOOR, EAST PALO ALTO, CA, 94303, US

(21) Appl. No.: 11/095,211

(22) Filed: Mar. 30, 2005

Related U.S. Application Data
(60) Provisional application No. 60/646,206, filed on Jan. 21, 2005.

(51) Int. Cl. G11C 5/06

(52) U.S. Cl. 365/63

(57) ABSTRACT

A storage controller comprising a first interface to exchange data with an appliance, such as a cell phone; a second interface to exchange data with a host system and receive power from the host system to provide power to the appliance; and a solid state memory to provide the appliance with storage for data.

### RELATED APPLICATIONS

This application claims the benefit of co-pending U.S. Provisional Application No. 60/646,206, entitled “Low-Power Solid State Storage Controller for Cell Phones and other Portable appliances,” filed Jan. 21, 2005 (Attorney Docket No. 006284.P015Z) and is incorporated herein by reference.

### BACKGROUND

Cell phones have been around for a long time (in terms of consumer electronic devices). Many of the chip sets used in cell phones have some limited flash memory, typically NOR flash, for storage of phone operating parameters, a small phone book, etc.; however, to store large volumes of data, NAND flash, with a real file system, is required. However, often the phone's currently available on the market are unable to support a larger memory device. It may be that the phone's chip set does not properly support additional memory.

What is clearly needed is an additional chip whose architecture allows large-capacity NAND flash or flash modules to be integrated into an existing cell phone chipset, thus allowing existing cell phone architectures to continue and to be extended. What is further needed is a solid-state storage controller that is able to operate at very low power when in stand-alone mode and to operate at very high speeds when connected to a computer system such as a personal computer or an Apple Macintosh.

### BRIEF DESCRIPTION OF THE DRAWINGS

FIG. 1 shows an overview of the enhanced cell phone system according to the novel art of this disclosure, in accordance with one embodiment.

FIG. 2 shows the various data flow directions available for cell phone, in accordance with one embodiment.

FIG. 3 shows an overview of the enhanced functionality of the phone architecture according to one embodiment.

### DETAILED DESCRIPTION

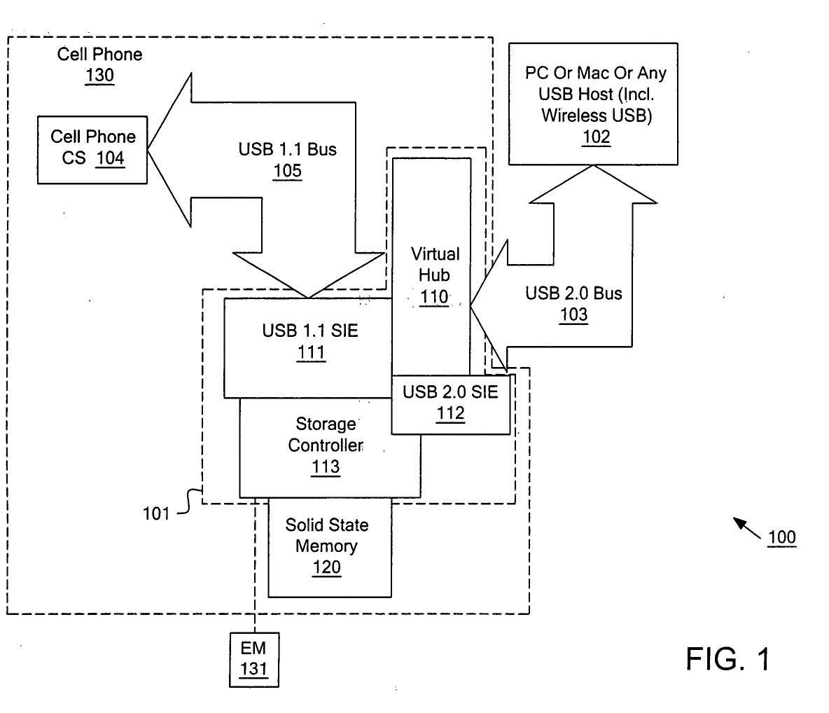

FIG. 1 shows an overview of the enhanced cell phone system 100 according to the novel art of this disclosure. Cell phone 130 contains an original cell phone chip set 104 (legacy phone core) that may have its own NOR flash for storage of phone numbers and system parameters (NOR flash not shown). It also has a USB serial connection 105 that typically would be connected to a PC. However, the transmission speed supported by connection 105 is not suitable for transfer of large amounts of data, and the phone's controller chip may not be able to handle the requirement of NAND flash. Important to the novel art of this disclosure is the addition of a storage controller chip 101, which contains a USB 1.1 serial interface engine (SIE) 111, a virtual hub 110, a USB 2.0 SIE 112, an actual storage controller (a CPU or microcontroller) 113. Typically, a solid-state memory 120 of a variety of types of NAND flash may be attached to chip 101. In addition, in some cases, an external flash memory EM 130 (such as Trans flash, xD card, SD card, Memory Stick, Memory Stick Duo etc.) may be connected to chip 101. A USB 2.0 connection 103 comes out of virtual hub 110, thus allowing connection of the system 100 to a USB host 102, such as a PC or Mac or any other type of USB host, including wireless USB and other devices. The virtual hub may in some cases appear as a USB 2.0 hub with two downstream ports. When the phone is connected to a PC, one of the downstream ports can report a high-speed USB (USB 2.0) mass storage device and the other port can report a full speed (USB 1.1) device. This enables the phone to be charged on the USB 1.1 port while content is being transferred to the mass storage device on the USB 2.0 port. Further, cell phones and other portable appliances such as Music player, Photo Viewer, Multimedia Center typically have a USB interface that can perform several functions, such as testing the final product in the manufacturing line, charging the battery of the portable appliance, acting as an expansion port to attach USB devices such as a keyboard, mouse or a joystick, and in a special case, an On The Go function port, which can be either a host or a slave. Portable appliances have severe constraints on the amount of power they can source. To manage various tasks and keep track of addresses, audio and video content, etc., it is desirable to have a means of storage that is low in power consumption and also very fast. Due to the fact that portable appliances need to consume very low power (cell phones for instance, cannot source more than 25 milliamps without an extra battery pack) the USB interface is built to be as power efficient as possible, foregoing performance in the process. With content growing in size (a typical MP3 music file takes 1 mega byte of storage for 1 minute of content) it is desirable that the content be transferred into the storage as quickly as possible.

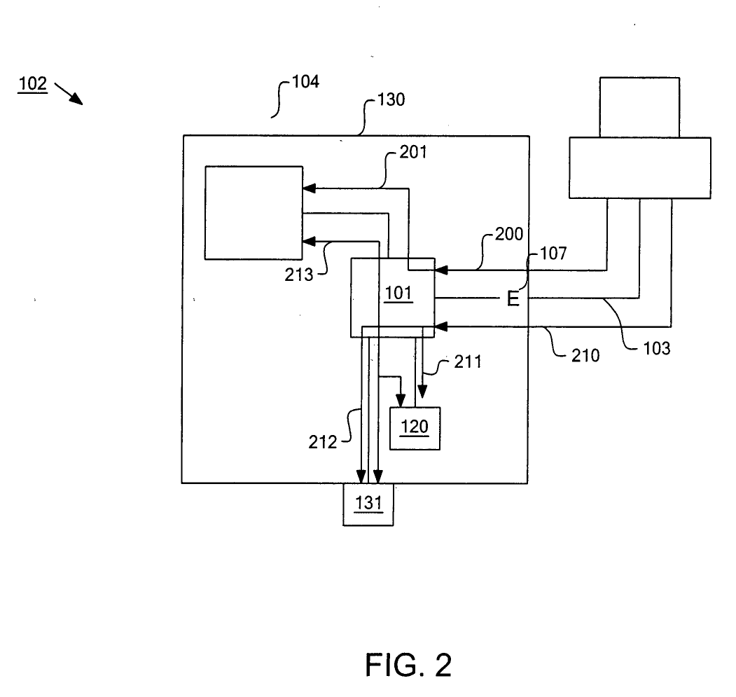

FIG. 2 shows the various data flow directions available for cell phone 130. PC 102 may access, through data flow lines 200 and 201, the original phone functions in a transparent manner. It may access the internal or external flash memory devices 120 and 131 with flow connections 210, 211, and 212. Or, the controller 101 may initiate an exchange between the original chipset 104 and the internal or external flash chips 120 and 131, respectively, with connection 213. In this case, typically, the controller 101 acts as USB master to the internal chip set 104, having access to memory and data, and the ability to transfer it as needed to the chip set. This approach could be used, for example, to store or retrieve pictures, sounds, videos, and any other similar files, including large address books that could not fit in the original NOR flash (not shown). Controller 101 is shown here as a separate chip in cell phone 130, but in future generations it may be integrated with existing chip set 104 to form a new chip set (not shown). This layering in some cases allows the phone to maintain software compatibility for older sections of the architecture (i.e., core phone functions, mass storage device functions), but add new features on top.

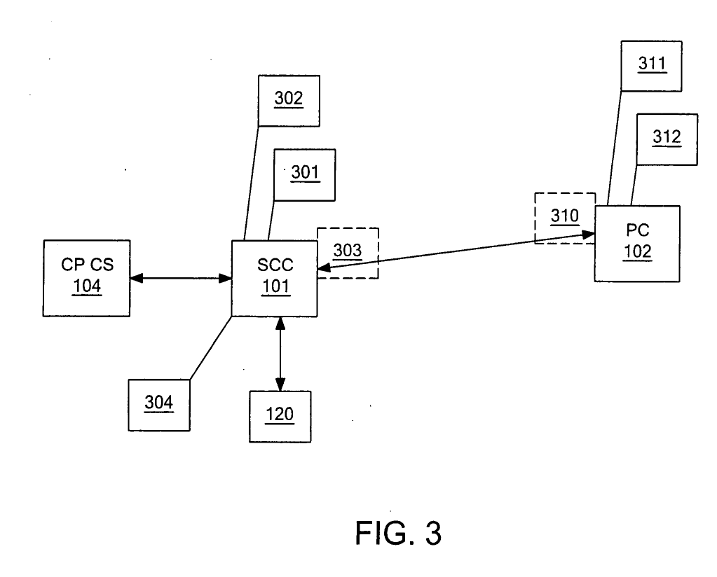

One approach that allows said layering is shown in FIG. 3, which shows an overview of the enhanced functionality of the phone architecture according to the novel art of this disclosure. In some cases, it is important to use two sets of multiplexers, software multiplexers 303 and 310, which allows the connections between the PC 102 and the storage controller chip (SCC) 101 to be used either for connection from the PC transparently into the original cell phone chip set (CPCS) 104, or, in another mode, to represent the internal flash 120 and, if present, the external flash 131 (not shown here) as a media drive. In this case, on the PC side, phone driver 311 for the legacy phone core is used, and a standard mass storage device driver 312 is used for the NAND flash (120 and or 131). If possible, the mass storage device driver 312 should be the standard driver used by the operating system, such as, for example, Windows and MacOS. Multiplexer 310 allows both drivers to access the same USB port concurrently and to transparently switch and allow concurrent access to both drivers 311 and 312. The SCC 101 takes those accesses that are intended for the CPCS 104 and passes them through, and it also takes those accesses that are intended for the flash (internal or external) and redirects them accordingly. Also, the CPCS 104 may issue requests as a slave to the SCC 101 to load data from one of the flash devices and move those into the CPCS. In some cases, for simplification of the multiplex function, the drivers would be allowed only to operate exclusively, such that either the memory or the phone functionality can be accessed. In other cases the multiplex functionality may be implemented with a higher granularity, allowing for concurrent use of the full connectivity by multiplexing the different protocols for the different accesses.

It is clear that many modifications and variations of this embodiment may be made by one skilled in the art without departing from the spirit of the novel art of this disclosure.

The processes described above can be stored in a memory of a computer system as a set of instructions to be executed. In addition, the instructions to perform the processes described above could alternatively be stored on other forms of machine-readable media, including magnetic and optical disks. For example, the processes described could be stored on machine-readable media, such as magnetic disks or optical disks, which are accessible via a disk drive (or computer-readable medium drive). Further, the instructions can be downloaded into a computing device over a data network in a form of compiled and linked version.

Alternatively, the logic to perform the processes as discussed above could be implemented in additional computer and/or machine readable media, such as discrete hardware components as large-scale integrated circuits (LSI's), application-specific integrated circuits (ASIC's), firmware such as electrically erasable programmable read-only memory (EEPROM's); and electrical, optical, acoustical and other forms of propagated signals (e.g., carrier waves, infrared signals, digital signals, etc.); etc.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims which in them selves recite only those features regarded as essential to the invention.

### Appendix A

### Appendix A: A Controller (C300) Specification Using the Above Concept

A low power, cost efficient and innovative solution to manage solid-state memory is proposed. Cell phones and other portable appliances such as Music player, Photo Viewer, Multimedia Center typically have a USB interface to perform several functions such as:
An interface to test the final product in the manufacturing line
To charge the battery of the portable appliance
Expansion port to attach USB devices such as a keyboard, mouse or a joystick
On The Go function port to be either a host or a slave

Portable appliances have severe constraints on the amount of power they can source. To manage various tasks and keep track of addresses, audio and video content etc. it is desired to have storage means which is low in power consumption and also very fast. Due to the fact that portable appliances need to consume very less power (cell phones for instance, cannot source more than 25 milli Amps without an extra battery pack) the USB interface is built to be as power efficient as possible, foregoing performance in the process. With content growing in size (a typical MP3 music file takes 1 Mega Byte of storage for 1 minute of content) it is desirable that the content be transferred into the Storage as quickly as possible.

It is therefore desirable to design a Solid State Storage Controller that will:
Operate at very low power when in stand alone mode
Operate at very high speeds when connected to a computer system such as a Personal Computer or an Apple Mac
FIG. 1. illustrates one such design.

[image]

When the phone is connected to a PC the Storage Controller will switch off the connection between SIE and Storage controller using software/ hardware means. The Virtual Hub handles most of the transactions in hardware. The Solid State Memory will appear as a Mass Storage Device, when connected to a PC or Mac. For more, please refer to FIG. 2.

[image]

The virtual hub will appear as a USB 2.0 Hub with 2 downstream ports. One of the downstream ports will report a Hi-Speed USB (USB 2.0) Mass Storage Device and the other port will report a Full Speed (USB 1.1) device. This enables the Portable appliance to get charged on the USB 1.1 port while content is being transferred to the Mass Storage Device on the USB 2.0 port.

When the Appliance is Disconnected From the PC/Mac the Following Events Occur:
A USB reset will be sent to the cell phone
The CPU will configure itself to be a host and establish a connection with the cell phone
A reverse protocol will allow data to be transferred between the phone and the Solid-state memory

### Reverse Protocol

In normal USB applications, the storage resides with the Slave device. In this instance, the opposite is true. The storage resides with the host and the data needs to be given to the Slave(Portable appliance) when the Slave(Portable appliance) is ready to receive it. One such instance would be when the Slave needs to display a picture or play an MP3 song. Since the host (Storage Controller) has no idea of when a storage request will come, the Storage controller polls the cell phone periodically to see if it needs any data by sending a In Token and receiving a block of data with an address, length, and flags to indicate a read or write. During any transfer the USB 2.0 port should be left off.

[image]

### Typical Reverse Protocol Transaction

Table 1 describes one method of implementation of the Reverse Protocol transaction. Some of the steps are redundant and are listed for completeness. This is merely a typical implication that illustrates this concept and should be afforded the maximum scope. For instance, the data can be sent on either Control pipe or Bulk pipes. The RequestFlags can also be implemented as a USB Mass Storage Command Block/Data In or Out and/USB Mass Storage Status Block. The Status phase of transactions are left out from the table for clarity.

TABLE 1
A typical Reverse Protocol Transaction

| Transaction | | Direction of | |
|---|---|---|---|
| sequence. | Storage Controller action | Command/Data | Portable device response |
| 1 | Storage Controller issues a Reset | → | Resets its address. |
| 2 | Host sets new address | → | Device accepts new address |
| 3 | Host requests device descriptor | → | Device gets ready to send descriptor data |
| | | [symbol] | Returns device descriptor data |
| 4 | Host requests configuration | → | Device gets ready to send configuration descriptor |
| | descriptor | | data |
| | | [symbol] | Returns configuration descriptor data |
| 5 | Host selects one of configurations | → | Accepts the configuration being set |
| 6 | Host requests a Poll For Device | → | Accepts the command and builds the request field |
| | Request | | |
| | | [symbol] | If Portable device has a request pending, it will do so |
| | | | by setting one of the bits in the RequestFlags field. |
| | Based on the request direction flag, | [symbol] /→ | According to the direction of data either sends or |
| | Host either receives data or sends | | receives data. |
| | data to the portable device | | |
| 7 | Once the data transfer finishes, waits | | |
| | at Step 6 for further commands. Host | | |
| | can optionally go into standby mode | | |
| | to conserve power | | |

TABLE 2
A typical set of definitions for RequestFlags

| SI. No. | Description | Value |
|---|---|---|
| 1 | Request for Data from the Solid-state memory | 0x0001 |
| 2 | Request for Data to the Solid-state memory | 0x0002 |

### Solid-State Storage Applications

Several applications are envisioned for the portable appliances and some of these are listed below:
1. Prepare (Format) Solid-state memory. Due to stringent power conditions, it is possible to accidentally write bad data to the solid-state memory when the power supply is running low. In such an event, the solid-state memory can stop responding or worse lose all the existing data. An application to recover the bad data and then restore the memory to factory set conditions is extremely useful.
2. A Data synchronization utility to ensure that the portable appliance can make a copy of its data on a Personal Computer or a Mac would be useful.
3. An Image creator application, which can capture the exact layout of the solid-state memory, as it exists on a portable device, so it can be analyzed in the factory, would be extremely helpful for technical support teams.

### Summary

This is just one instance of how this Controller can be used. PC or Mac or any USB Hosts (including but not limited to USB On The Go hosts) can be used to interface with this controller. The link can be a USB wire or Wireless USB. The Reverse Protocol transaction could be PictBridge based instead of Mass Storage Class. The solid-state memory could be replaced by magnetic memory and the concept would still hold good. It is therefore requested that the patent be offered the widest scope possible.

1) A storage controller comprising:
a first interface to exchange data with an appliance;
a second interface to exchange data with a host system and to provide power to the appliance; and
a solid state memory to provide the appliance with storage for data.

2) The storage controller of claim 1, wherein the solid state memory comprises NAND flash memory.

3) The storage controller of claim 1, wherein the first interface comprises a first Universal Serial Bus (USB).

4) The storage controller of claim 1, wherein the second interface comprises a second USB interface.

5) The storage controller of claim 1 further comprises a first USB serial interface engine (SIE), a virtual hub, a second USB SIE, and a microcontroller.

6) The storage controller of claim 1, wherein the solid state memory comprises an external flash memory.

7) The storage controller of claim 4, wherein the second USB interface is coupled to a virtual hub of the storage controller.

8) The storage controller of claim 7, wherein the virtual hub is to appear to the system as a USB hub having two downstream ports.

9) The storage controller of claim 8, wherein a first downstream port is a first speed storage device, and a second down stream port is second speed storage device, wherein the first speed is greater than the second speed, to enable the appliance to receive power from the system via the first interface and concurrently have data exchanged with the memory via the second interface.

10) The storage controller of claim 1, wherein the appliance comprises one of a cellular phone, a music player, and a photo viewer.

11) The storage controller of claim 1 provided as a discrete component.

12) The storage controller of claim 1 provided as an integrated with a chipset of the appliance.

13) The storage controller of claim 1, further comprising a first multiplexer at the storage controller and a second multiplexer at the system, the first and second multiplexer to allow connections between the system and the appliance transparently through the storage controller in a first mode of operation, and connections to represent the memory as a media drive in a second mode of operation.

14) The storage controller of claim 13, wherein the system is to include a first driver for interfacing with the appliance, and a second media driver for interfacing with the memory, and second multiplexer is to allow the first and second drivers of the system to access the second interface of the storage controller.

15) The storage controller of claim 14, wherein the second multiplexer is to allow the first and second drivers of the system to access the second interface of the storage controller concurrently.

16) The storage controller of claim 14, wherein the second multiplexer is to allow the first and second drivers of the system to access the second interface of the storage controller exclusively.

17) The storage controller of claim 1, wherein the controller is to receive a request from the appliance to load data from the memory onto the appliance.

18) A storage controller comprising:
a first interface means to exchange data with an appliance;
a second interface means to exchange data with a host system and to provide power to the appliance; and
a solid state memory means to provide the appliance with storage for data.

19) The storage controller of claim 4, wherein the first USB interface and second USB interface are dissimilar, and are selected from a group comprising USB 1.1, USB 2.0, USB 1.1 OTG, USB 2.0 OTG, Wireless USB.
